(19) United States
(12) Patent Application Publication
(10) Pub. No.: US 2017/0030987 A1
(43) Pub. Date: Feb. 2, 2017

(54) SCAN CONDITION SETTING APPARATUS AND METHOD OF SETTING SCAN CONDITION ON A MAGNETIC RESONANCE IMAGING SYSTEM

(71) Applicant: General Electric Company, Schenectady, NY (US)

(72) Inventors: Kenji Suzuki, Hino-shi (JP); Antoine CHOPPIN, Hino-shi (JP)

(21) Appl. No.: 15/289,606

(22) Filed: Oct. 10, 2016

Related U.S. Application Data
(63) Continuation of application No. 12/942,205, filed on Nov. 9, 2010, now abandoned.

(30) Foreign Application Priority Data
Nov. 9, 2009 (JP) 2009-255618

(51) Int. Cl. G01R 33/54; G01R 33/56

(52) U.S. Cl. CPC G01R 33/543; G01R 33/546; G01R 33/5602

(57) ABSTRACT

A scan condition setting apparatus sets a scan condition used upon scanning a subject. The apparatus includes a selection device having a plurality of combinations of scan times and image quality and selecting one from within the combinations according to a manipulation of an operator, and a scan condition storage device for storing scan conditions corresponding to the combinations of the scan times and image quality therein. The scan condition corresponding to the combination of the scan times and image quality selected by the selection device is set as the scan condition used when the subject is scanned.

### CROSS REFERENCE TO RELATED APPLICATIONS

This application claims the benefit of Japanese Patent Application No. 2009-255618 filed on Nov. 9, 2009 and is a continuation patent application of U.S. patent application Ser. No. 12/942,205 filed on Nov. 9, 2010, which are hereby incorporated by reference in their entireties.

### BACKGROUND

The present invention relates to a scan condition setting apparatus for setting a scan condition on a magnetic resonance imaging (MRI) system.

An operator needs to set an imaging or scan condition before imaging a subject. As the number of scan conditions to be set increases, the burden on the operator becomes large. There has therefore been proposed a method for making it possible to quickly and easily select and set scan parameters or the like (refer to Japanese Unexamined Patent Publication No. 2003-225222).

The method according to the above-referenced document enables adjustments of parameters dominant over image contrast every scanning. However, in general, it is not easy to understand the degree of change of the image contrast where the parameters are adjusted. A problem therefore arises in that it is difficult to adjust the parameters in such a manner that suitable image contrast is obtained.

Therefore, it is desirable that the problem described above is solved.

### SUMMARY

A first aspect of the invention is to provide a scan condition setting apparatus which sets a scan condition used when a subject is scanned, including: a selection device having a plurality of combinations of scan times and image quality and selecting one from within the combinations according to a manipulation of an operator; and a scan condition storage device for storing scan conditions corresponding to the combinations of the scan times and image quality therein, wherein the scan condition corresponding to the combination of the scan times and image quality selected by the selection device is set as the scan condition used when the subject is scanned.

Further, a second aspect of the invention is to provide a scan condition setting apparatus which sets a scan condition used when a subject is scanned, including: a selection device having a plurality of choices each indicative of a difference in the width of a field of view and selecting one from within the choices according to a manipulation of an operator; and a scan condition storage device for storing scan conditions corresponding to the respective choices therein, wherein the scan condition corresponding to the choice selected by the selection device is set as the scan condition used when the subject is scanned.

The scan condition setting apparatus according to the first aspect of the invention stores scan conditions corresponding to respective combinations of scan times and image quality therein. Accordingly, an operator simply selects one from within a plurality of combinations of scan times and image quality to thereby set a scan condition corresponding to the selected combination. It is therefore possible to easily set the scan condition.

The scan condition setting apparatus according to the second aspect of the invention stores therein scan conditions corresponding to respective choices each selectable as a width of a field of view. Accordingly, an operator simply selects one from within a plurality of choices to thereby set a scan condition corresponding to the selected choice. It is therefore possible to easily set the scan condition.

Further objects and advantages of the present invention will be apparent from the following description of the preferred embodiments of the invention as illustrated in the accompanying drawings.

### BRIEF DESCRIPTION OF THE DRAWINGS

FIG. 1 is a schematic diagram showing a magnetic resonance imaging apparatus according to a first embodiment of the invention.

FIG. 2 is a diagram for explaining a flow used when an operator 14 makes a scan plan.

FIG. 3 is a diagram illustrating one example of a display screen displayed on a display device 12.

FIG. 4 is a diagram showing main items for each scan condition displayed in a display window 121 and the meaning thereof.

FIG. 5 is a diagram depicting one example of a procedure in which the operator 14 changes the setting of a scan condition.

FIG. 6 is a diagram showing one example of a procedure in which the operator 14 changes the setting of a scan condition.

FIG. 7 is a diagram illustrating one example of a procedure for changing the setting of an item “Scan Plane”.

FIG. 8 is a diagram depicting one example of a procedure for changing the setting of the item “Scan Plane”.

FIG. 9 is a diagram for explaining items can automatically be changed by the operator 14 while confirming a relationship between scan time and image quality.

FIG. 10 is a diagram showing one example of a display window 123 for making it possible to automatically change a scan condition related to a group G of items while confirming a relationship between scan time and image quality.

FIG. 11 is a diagram for describing a relationship between the position of a slider 124a and scan conditions.

FIG. 12 is a diagram illustrating the manner in which the slider 124a is moved to a left-edge scale M1.

FIG. 13 is a diagram showing a display screen after having been returned to a display window 121.

FIG. 14 is a diagram depicting one example of a display screen for displaying a slider bar 124 employed in a second embodiment.

### DETAILED DESCRIPTION

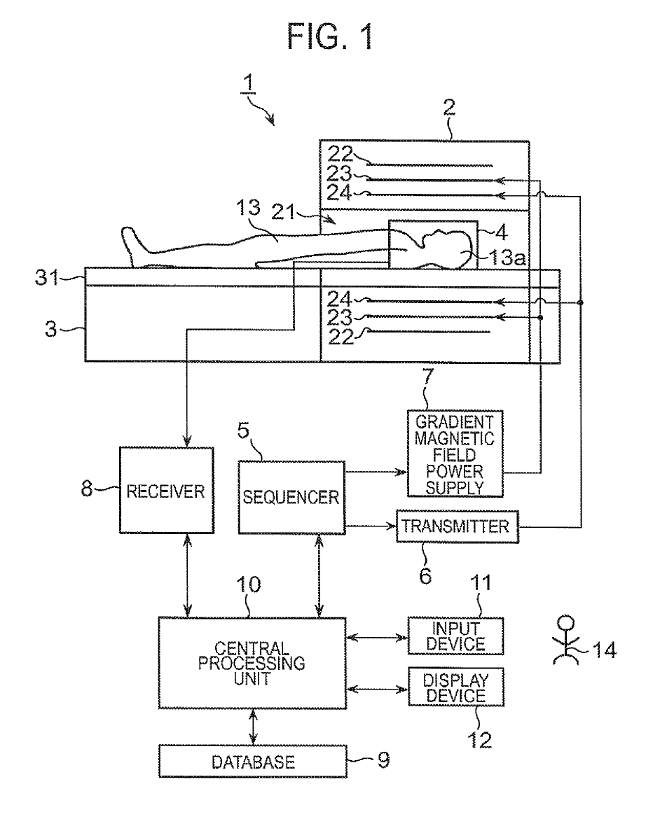

FIG. 1 is a schematic diagram showing a magnetic resonance imaging apparatus according to a first embodiment of the invention.

The magnetic resonance imaging apparatus (hereinafter referred to as MRI (Magnetic Resonance Imaging) apparatus) 1 has a magnetic field generator 2, a table 3, a reception coil 4, etc.

The magnetic field generator 2 has a bore 21 in which a subject 13 is accommodated, a superconductive coil 22, a gradient coil 23 and a transmission coil 24. The superconductive coil 22 applies a static magnetic field BO and the gradient coil 23 applies a gradient pulse. The transmission coil 24 transmits an RF pulse.

The table 3 has a cradle 31 for conveying the subject 13. The subject 13 is conveyed to the bore 21 by the cradle 31.

The reception coil 4 is attached to a head region 13a of the subject 13 and receives each magnetic resonance signal from the head region 13a.

The MRI apparatus 1 further has a sequencer 5, a transmitter 6, a gradient magnetic field power supply 7, a receiver 8, a database 9, a central processing unit 10, an input device 11 and a display device 12.

Under the control of the central processing unit 10, the sequencer 5 transmits information about an RF pulse (center frequency, bandwidth and the like) to the transmitter 6 and sends information about a gradient magnetic field (strength of gradient magnetic field, etc.) to the gradient magnetic field power supply 7.

The transmitter 6 drives the transmission coil 24, based on the information transmitted from the sequencer 5.

The gradient magnetic field power supply 7 drives the gradient coil 23, based on the information sent from the sequencer 5.

The receiver 8 signal-processes each magnetic resonance signal received by the reception coil 4 and transmits it to the central processing unit 10.

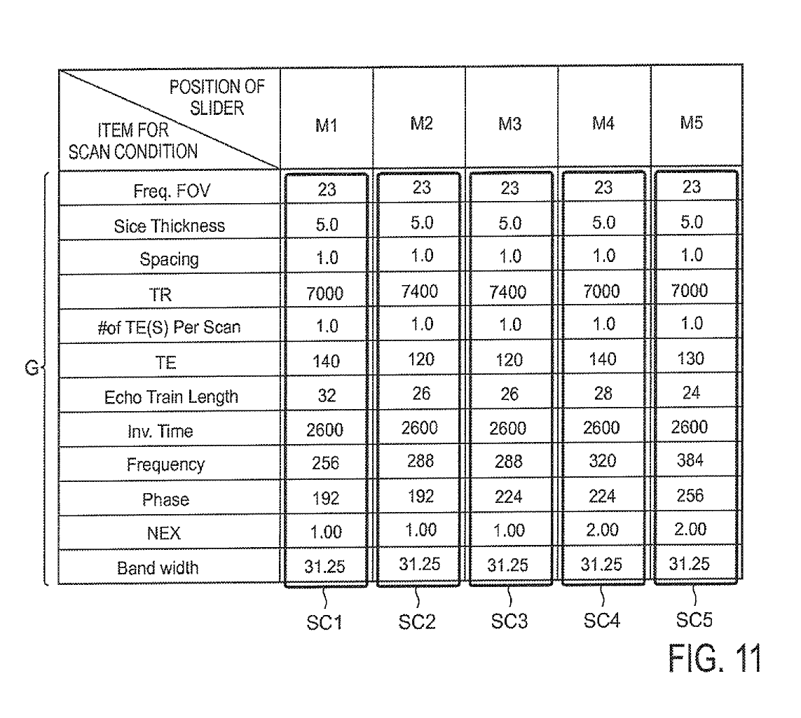

The database 9 stores scan conditions SC1 through SC5 (refer to FIG. 11 to be described later) therein.

The central processing unit 10 generally controls the operations of respective parts of the MRI apparatus 1 so as to realize various operations of the MRI apparatus 1 such as reconstruction of an image based on each signal received from the receiver 8, etc. Further, the central processing unit 10 controls the display device 12, based on information inputted via the input device 11 by the operator 14 in such a manner that the required scan condition is displayed out of the scan conditions SC1 through SC5 stored in the database 9. The central processing unit 10 includes, for example, a computer. Incidentally, the central processing unit 10 is one example illustrative of a selection device employed in the invention and functions as a selection device by executing a predetermined program.

The input device 11 inputs various instructions to the central processing unit 10 according to the manipulation of the operator 14. The display device 12 displays various information thereon.

The MRI apparatus 1 is configured as described above.

When the subject 13 is scanned using the MRI apparatus 1, the operator 14 sets up a scan plan in advance. A description will be made below of how the operator 14 sets up a scan plan.

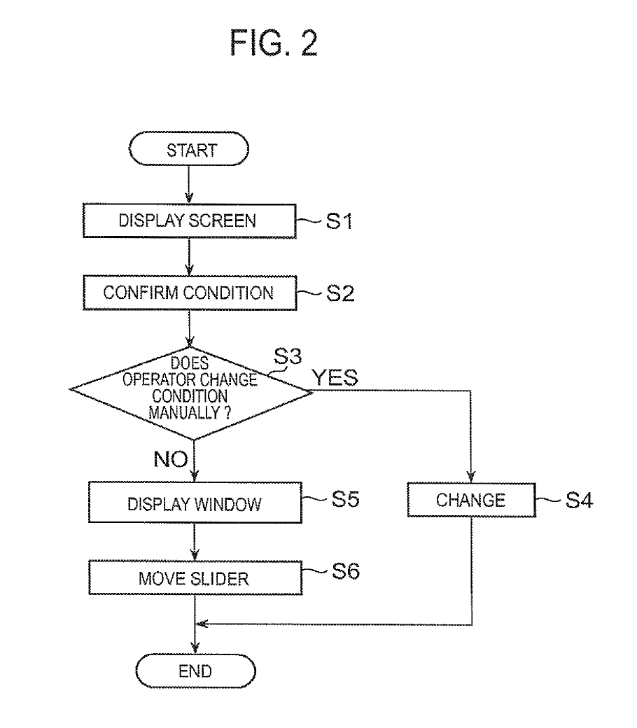

FIG. 2 is a diagram for describing a flow used when the operator 14 sets up the scan plan.

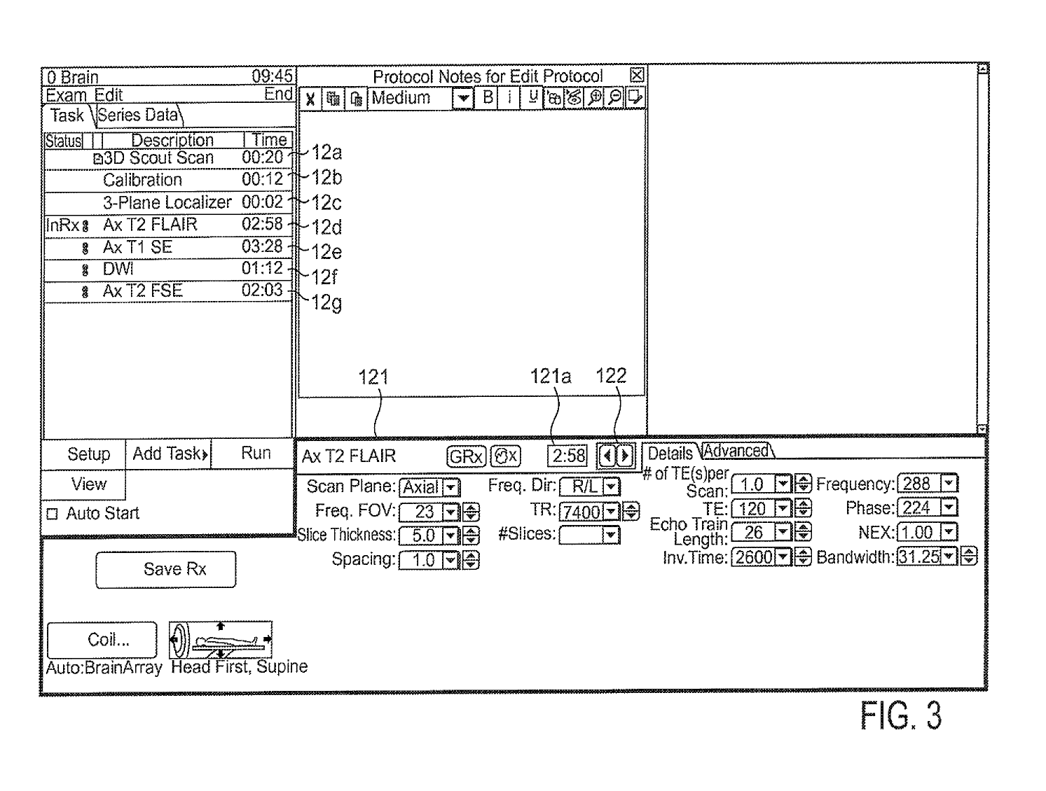

At Step 51, the operator 14 manipulates the input device 11 to display a screen for setting a scan condition on the display device 12 (refer to FIG. 3).

FIG. 3 is a diagram showing one example of a display screen displayed on the display device 12.

Several tasks 12a through 12g are carried out upon imaging of the subject 13 are displayed at the upper left of the display screen. The term task defines a scan condition or the like of the subject 13. For example, the task 12d defines a scan condition or the like where a T2 enhanced image of the head of the subject 13 is acquired by a Flair (Fluid Attenuated Inversion Recovery) method. After the display screen has been displayed, the operator 14 proceeds to Step

S2.

At Step S2, the operator 14 checks or confirms scan conditions or the like related to the tasks 12a through 12g. When the operator 14 considers a desire to confirm the scan condition related to the task 12d, for example, the operator 14 manipulates the input device 11 to select the task 12d. With the selection of the task 12d, the scan condition or the like related to the task 12d is displayed in a display window 121 at the lower part of the display screen. A scan time 121a is also displayed in the display window 121. In FIG. 3, a scan time ST is “2′58″”. The scan condition has a plurality of items. The items for each scan condition will be explained below.

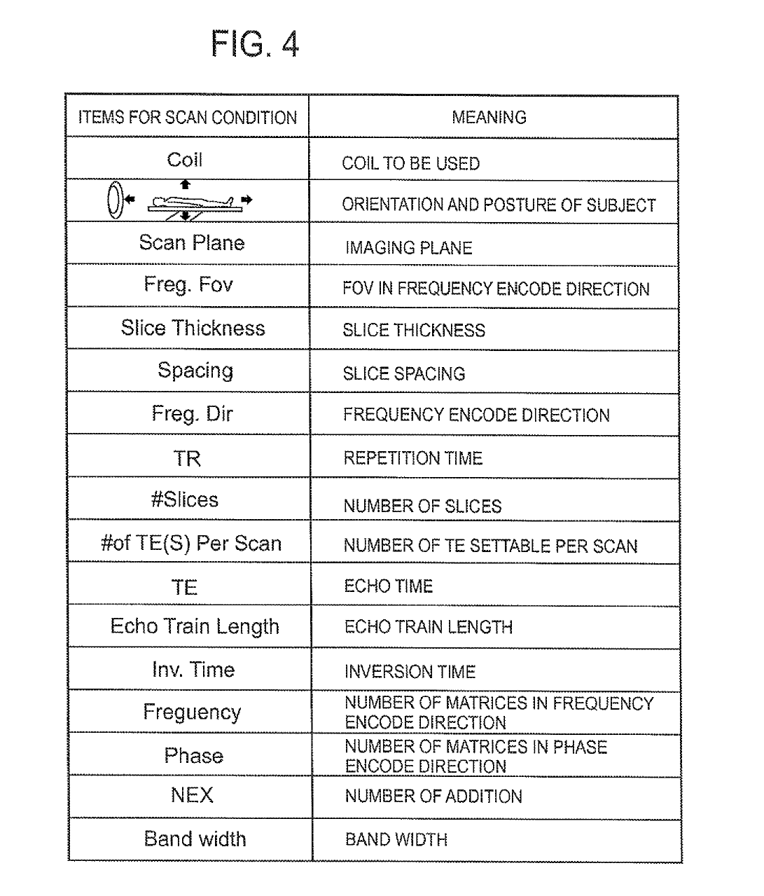

FIG. 4 is a diagram showing main items for each scan condition displayed in the display window 121, and the meaning thereof.

The operator 14 is able to confirm a scan condition by referring to the display window 121. After the scan condition has been confirmed, the operator 14 proceeds to Step S3.

At Step S3, the operator 14 determines whether the scan condition should be changed manually.

The operator 14 is not able to change the values of two items (number of TE(s) per Scan, and Echo Train Length) of the items for the scan condition. The operator 14 himself/herself is however able to change the values of other items. Thus, when it is desired to shorten the scan time, the operator 14 reduces the value of an item “Phase” or reduces the value of an item “Freq. FOV”, for example, thereby making it possible to shorten the scan time. When it is desired to enhance the resolution, the operator 14 makes the value of the item “Phase” larger, for example, thereby enabling an increase in the resolution. Thus, when the operator 14 wants to manually change the setting of the scan condition displayed in the display window 121, the operator 14 proceeds to Step S4.

At Step S4, the operator 14 changes the setting of the scan condition.

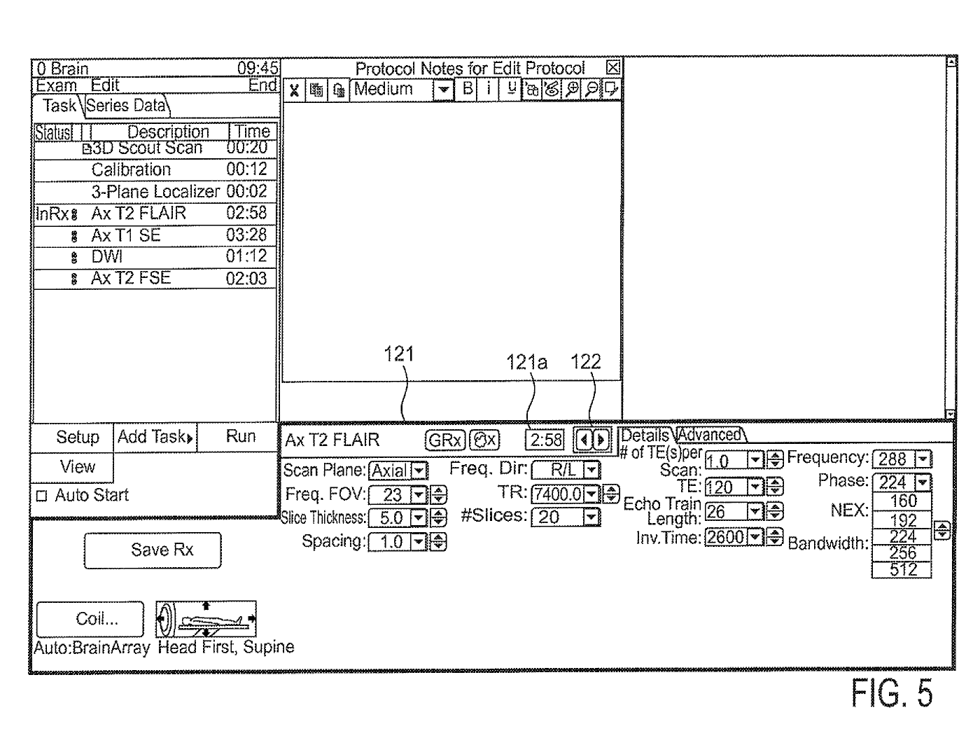

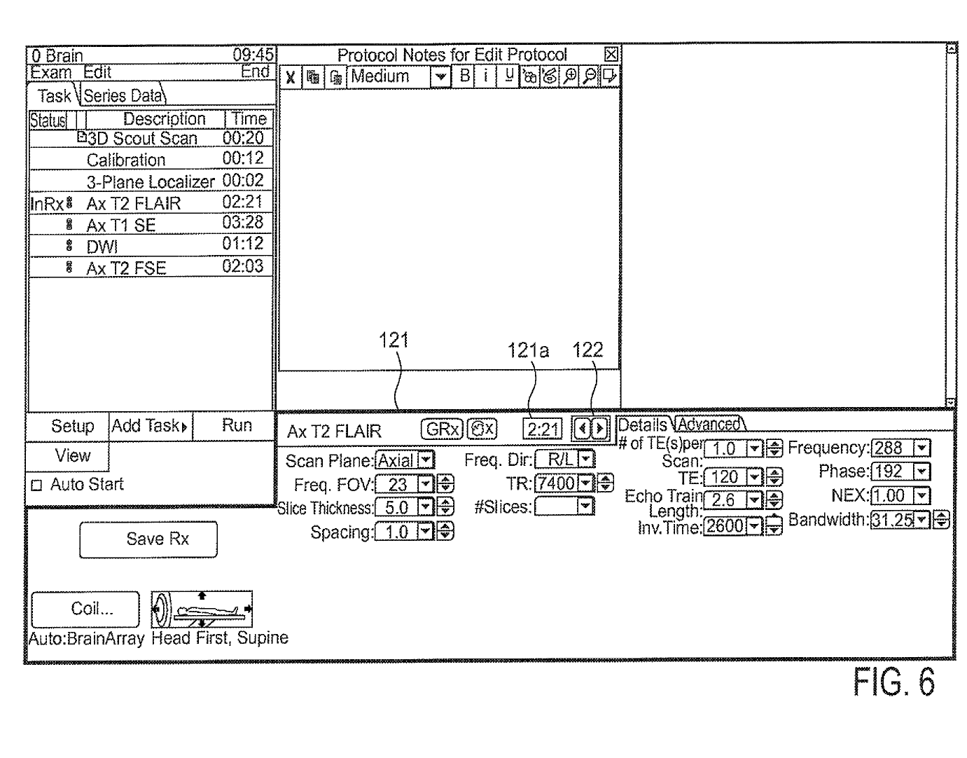

FIGS. 5 and 6 are diagrams each showing one example of a procedure in which the operator 14 changes the setting of a scan condition.

FIG. 5 shows an example in which the operator 14 changes the setting of the item “Phase” in the scan condition. The operator 14 manipulates the input device 11 to display each candidate value of the item “Phase”. In FIG. 5, as the candidate values of the item “Phase”, there are mentioned “160”, “192”, “252” and “512” in addition to “224”. The operator 14 selects one from a plurality of candidate values. When the operator 14 selects the candidate value “192”, for example, the item “Phase” is “192” as shown in FIG. 6. It is understood that when FIGS. 5 and 6 are compared with each other, the scan time 121a is shortened from “2′58” to “2′21” by changing the item “Phase” from “224” to “192”.

Although the procedure for changing the setting of the item “Phase” has been explained in FIGS. 5 and 6, the setting of another item can be adjusted in a similar procedure even where the setting thereof is altered. A procedure for changing the setting of an item “Scan Plane” will be described below as an example in which the setting of another item is changed.

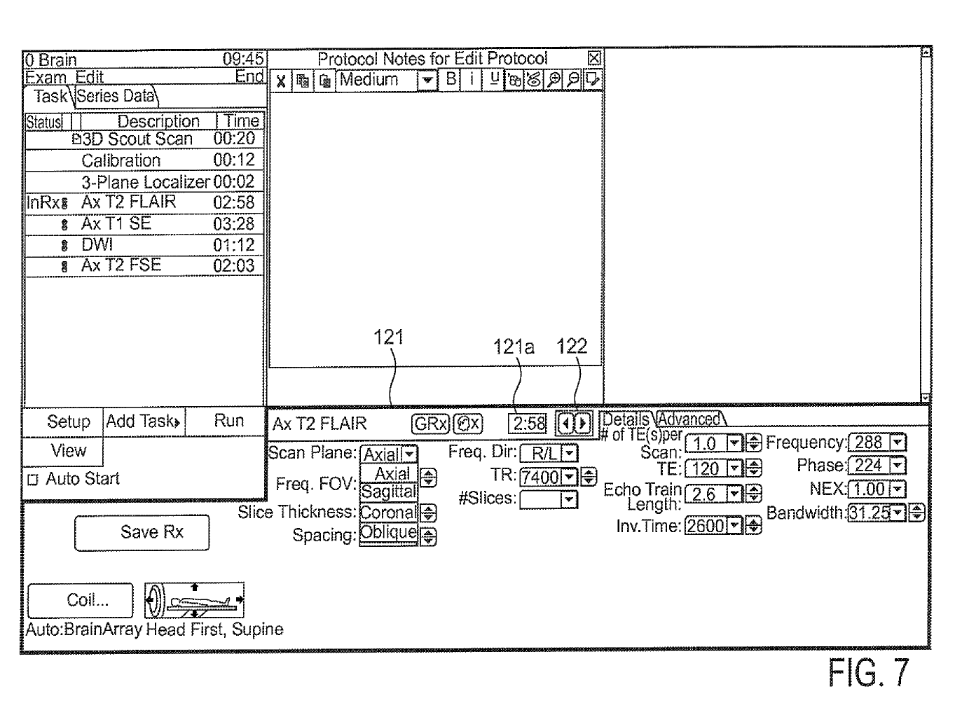

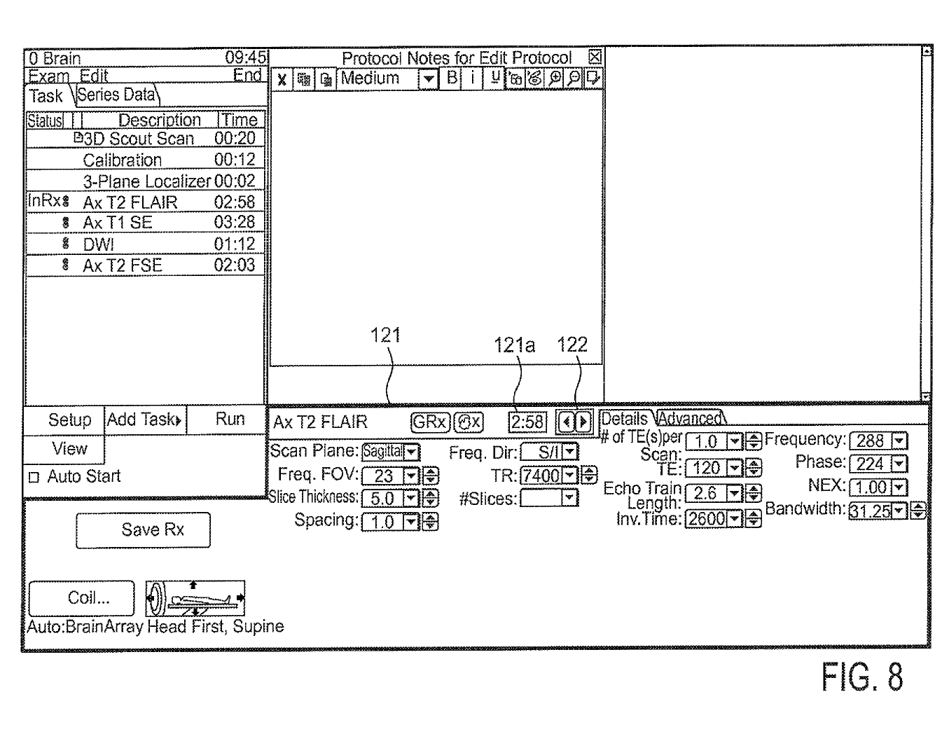

FIGS. 7 and 8 are diagrams each showing one example the procedure for changing the setting of the item “Scan Plane”.

The operator 14 operates the input device 11 to display each candidate of the item “Scan Plane” as shown in FIG. 7. Since “Coronal”, “Sagittal” and “Oblique” exist in addition to “Axial” as the candidates of Scan Plane, the operator 14 selects one out of plural candidates. When the operator 14 selects the corresponding candidate, the selected candidate is displayed in the column of the item “Scan Plane”. FIG. 8 shows a screen taken when “Sagittal” is selected. “Sagittal” means that a scan plane is set to a sagittal plane. When the item “Scan Plane” is set to “Sagittal”, an item “Freq. Dir” is automatically set to “S/I” (“S/I” means that a frequency encode direction is set to an SI direction).

When the operator 14 has finished changing the contents of the scan condition in accordance with the above procedure, the flow shown in FIG. 2 is completed.

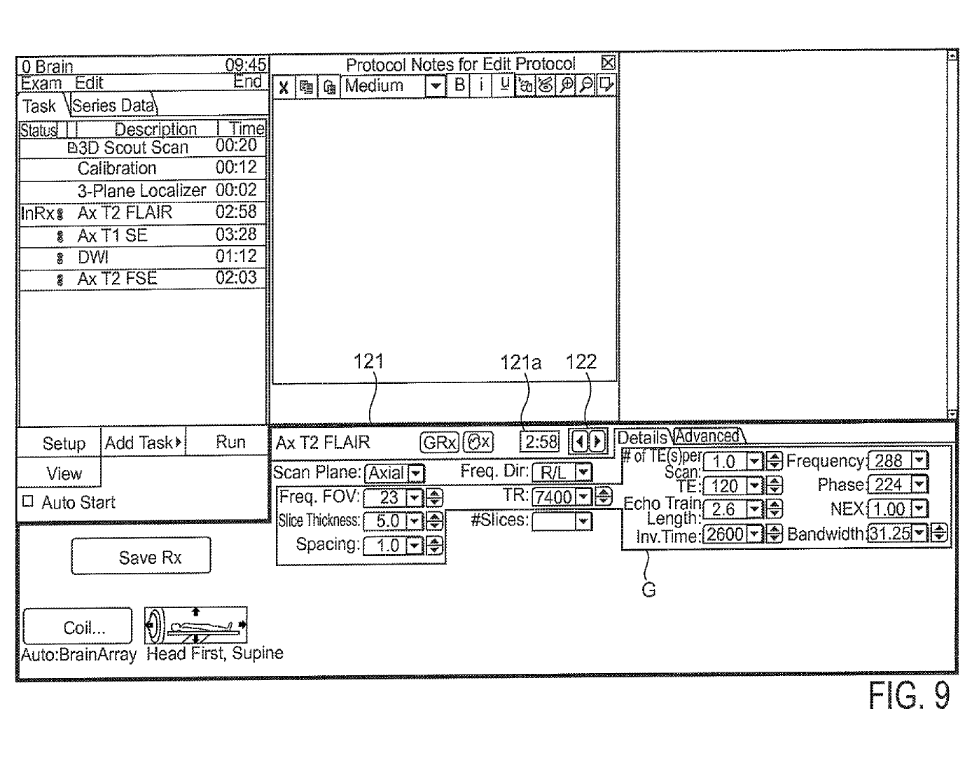

When, however, the contents of the scan condition are changed, they can influence image quality. Generally, it is not easy to anticipate to what extent the image quality is affected by the change in the contents of the scan condition. Thus, although the scan time can be shortened by changing the contents of the scan condition, the total imaging or scanning time may become long with the execution of a rescan where the quality of an acquired image is worse than the operator 14 thought. This is not preferred because a burden on the subject 13 becomes larger in reverse. Thus, in the present embodiment, the main items for the scan condition displayed in the display window 121 are configured in such a manner that the operator 14 is able to automatically change the set contents thereof while confirming the relationship between the scan time and image quality. Of the items for the scan condition displayed in the display window 121, the items in which the operator 14 is able to automatically change the set contents thereof while confirming the relationship between the scan time and image quality, will be explained below with reference to FIG. 9.

FIG. 9 is a diagram for explaining the items in which the operator 14 is able to automatically change the set contents thereof while confirming the relationship between the scan time and image quality.

In the present embodiment, in the case of a group G of predetermined items lying in the items displayed in the display window 121, the operator 14 is able to automatically change the set contents thereof while confirming the relationship between the scan time and image quality. Incidentally, like items “Coil” and “Scan Plane”, items can preferably be changed at random by the operator 14 are not contained in the group G.

When the operator 14 considers a desire to automatically change the scan condition related to the group G of the items while confirming the relationship between the scan time and image quality, the operator 14 proceeds from Step S3 to Step 5.

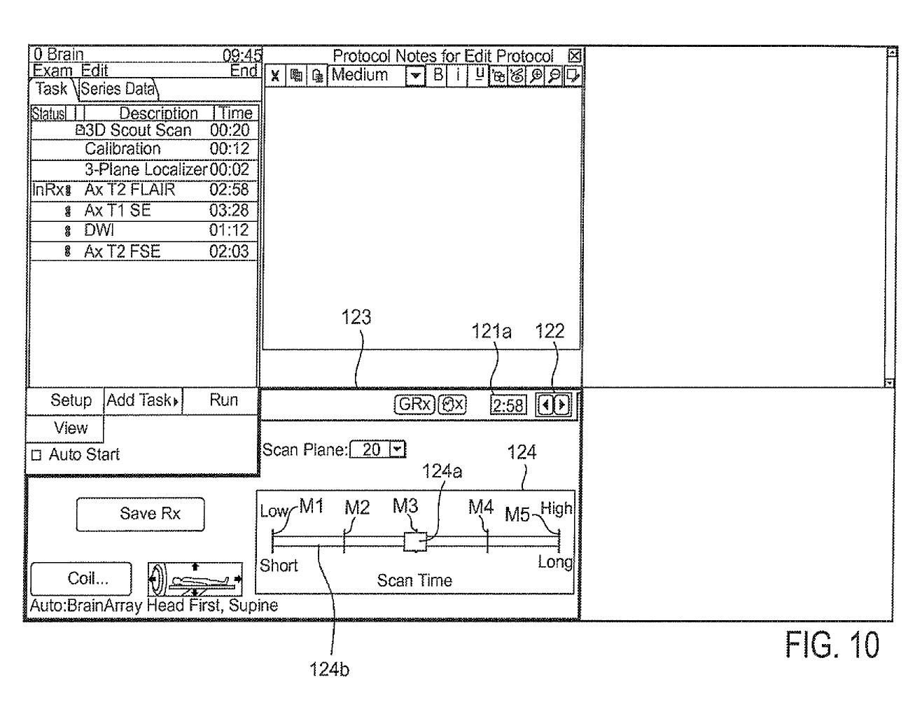

At Step S5, the operator 14 is caused to display a display window for allowing the operator 14 to automatically change the scan condition related to the group G of the items while confirming the relationship between the scan time and image quality (refer to FIG. 10).

FIG. 10 is a diagram showing one example of the display window 123 for making it possible to automatically change the scan condition related to the group G of the items while confirming the relationship between the scan time and image quality.

The display screen is provided with a window switch button 122 for selecting a display window. With the manipulation of this button 122, the operator 14 is able to display the display window 123 for making it possible to automatically change the scan condition related to the item group G (refer to FIG. 9) while confirming the relationship between the scan time and image quality.

A slider bar 124 for selecting the relationship between the scan time and image quality is displayed in the display window 123. The slider bar 124 has a slider 124a and a bar 124b for defining a range in which the slider 124a is movable. The bar 124b is marked with scales M1 through M5 for indicating the relationship between the scan time and image quality in five levels. The scales M1 through M5 means that the image quality become better as the scale moves from the scale M1 on the far left to the scale M5 on the far right, but the scan time becomes longer. The scan condition related to the item group G is automatically adjusted by allowing the operator 14 to adjust the position of the slider 124a. A description will be made below of how the scan condition is adjusted according to the position of the slider.

FIG. 11 is a diagram for explaining a relationship between the position of the slider 124a and a scan condition.

A group G (refer to FIG. 9) of main items in each scan condition is shown in FIG. 11. The five scan conditions SC1 through SC5 have been registered in the database 9 (refer to FIG. 1) in advance as the scan conditions each related to the item group G. When the operator 14 moves the slider 124a to the left-edge scale M1, the scan condition SC1 is selected. The contents of the item group G are set in such a manner that the scan condition SC1 becomes the worst in image quality but the shortest in scan time within the scan conditions SC1 through SC5. The scan conditions SC2, SC3, SC4 and SC5 are selected in order as the operator 14 moves the slider 124a from the left-edge scale M1 to the scales M2, M3, M4 and M5 in order. As the position of the slider 124a approaches the right-edge scale M5, the scan conditions SC1 through SC5 are set in such a manner that the image quality takes priority over the scan time. When the slider 124a is moved to the right-edge scale M5, the scan condition SC5 is selected. The contents of the item group G are set in such a manner that the scan condition SC5 becomes the longest in scan time but the best in image quality within the scan conditions SC1 through SC5.

As one example of a method for determining the scan conditions SC1 through SC5 shown in FIG. 11, there is considered a method for scanning a lot of subjects 13 while the condition for setting the item group G is being changed, and determining each of the scan conditions in consideration of the quality of an actually-acquired MR image and an actually-taken scan time.

After the display window 123 has been displayed as shown in FIG. 10, the operator 14 proceeds to Step S6.

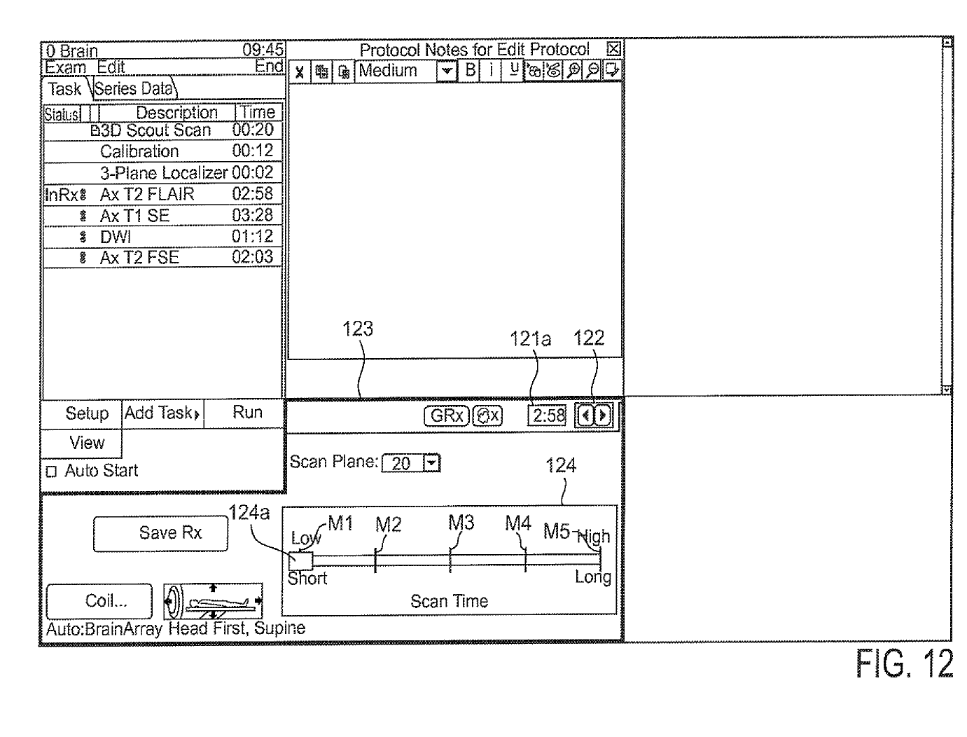

At Step S6, the operator 14 moves the slider 124a in consideration of a relationship between the scan time and image quality that the operator 14 himself/herself desires. When, for example, top priority is assigned to shortening the scan time as much as possible (imaging of an urgent patient and the like), the shortening of the scan time is more important than an improvement in image quality. Therefore, the operator 14 moves the slider 124a to the left-edge scale M1 in this case (refer to FIG. 12).

FIG. 12 is a diagram showing the manner in which the slider 124a is moved to the left-edge scale M1.

When the slider 124a is moved to the left-edge scale M1, the scan condition SC1 under which a scan can be executed in the shortest scan time although the image quality is worse, is automatically selected. It is thus possible to obtain an image of the subject 13 in a short period of time as the operator 14 wishes. The scan condition SC1 is automatically selected by allowing the operator 14 to merely move the slider 124a to the left-edge scale M1 even without causing the operator 14 himself/herself to individually change the setting of the items lying in the display window 121 (refer to FIG. 3), thereby making it possible to set the scan condition SC1 simply.

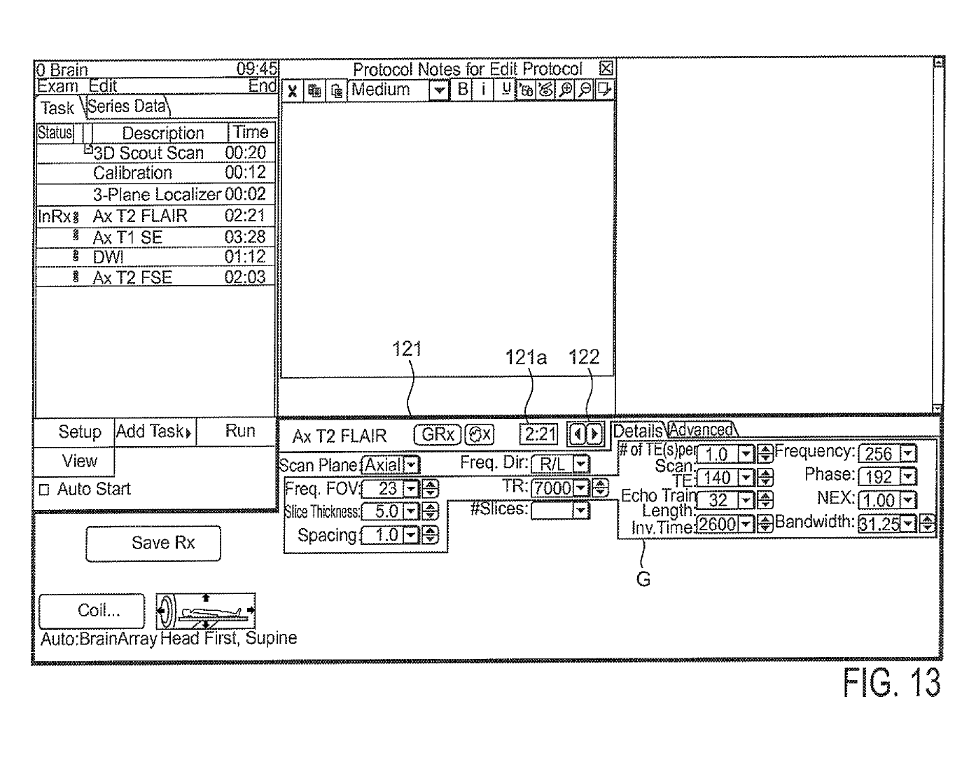

Incidentally, the operator 14 can also confirm the contents of the scan condition SC1 selected where the slider 124a is shifted to the left-edge scale M1. When it is desired to check the contents of the scan condition SC1, the operator 14 manipulates the window switch button 122 to return to the display window 121 indicative of the scan condition (refer to FIG. 13).

FIG. 13 is a diagram showing a display screen after having been returned to the display window 121.

It is understood that referring to the display window 121 shown in FIG. 13, the scan condition SC1 is set with respect to the item group G.

Incidentally, although the above description has been made of the case where the scan time is assigned top priority, there is a case where top priority is assigned to obtaining a high-quality image. Since an improvement in image quality is more important than shortening of the scan time in this case, the operator 14 moves the slider 124a to the right-edge scale M5. Thus, since the scan condition SC5 set in such a manner that the scan time is long but the image quality becomes the best is selected, the operator 14 is able to obtain an image good in image quality as the operator 14 wishes. Since the scan condition SC5 is automatically selected by allowing the operator 14 to merely move the slider 124a to the right-edge scale M5, the scan condition SC5 can simply be set. When it is desired to confirm the scan condition SC5, the operator 14 may click the window switch button 122 and return to the display window 121.

When both of the image quality and the scan time are given priority, the operator 14 moves the slider 124a to the central scale M3. In this case, it is possible to select the scan condition SC3 for scanning the subject 13 in such a manner that the image quality is not so worse, but the scan time is not so long. Further, the operator 14 is also able to select the scan condition SC2 or SC4 by moving the slider 124a to the scale M2 or M4 as needed.

Although the slider bar 124 is configured so as to be capable of selecting the combination of the scan time and the image in the first embodiment, a slider bar 124 employed in a second embodiment is configured so as to be capable of selecting the width of a field of view therein. The slider bar 124 employed in the second embodiment will be explained below. Incidentally, a hardware configuration according to the second embodiment is identical to that of the first embodiment.

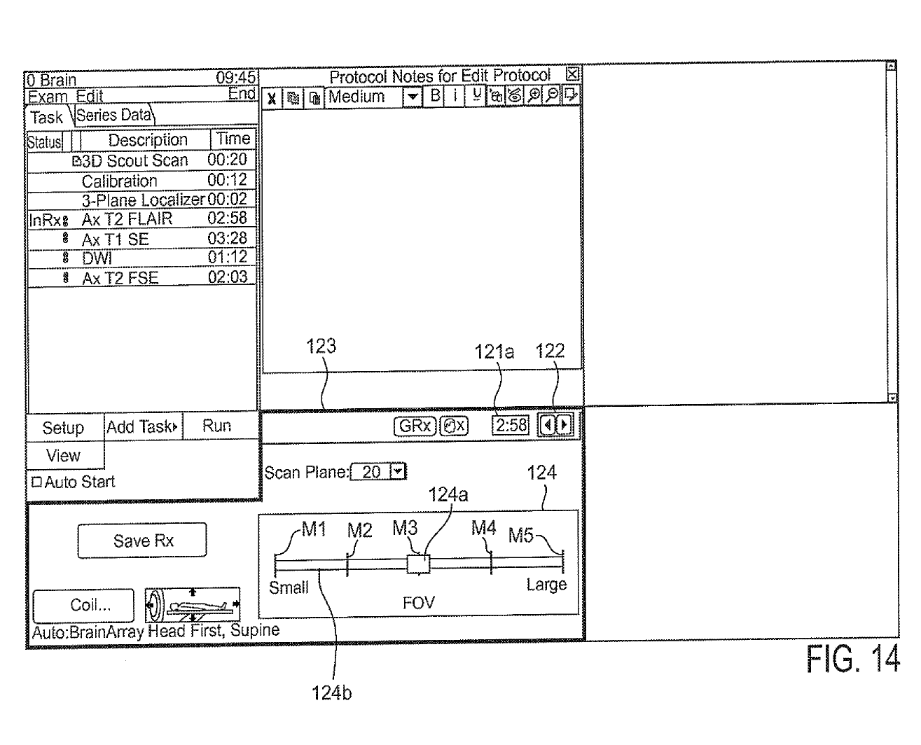

FIG. 14 is a diagram showing one example of a display screen for displaying the slider bar 124 employed in the second embodiment.

The slider bar 124 for selecting the width of a field of view FOV is displayed in a display window 123. The slider bar 124 has a slider 124a, and a bar 124b for defining a range in which the slider 124a is movable. The bar 124b is marked with scales M1 through M5 for enabling the width of the field of view FOV to be selected from within five choices extending from the narrowest “Small” to the widest “Large”. The scales M1 through M5 means that the field of view FOV gradually becomes wider as the slider 124a moves from the left-edge scale M1 to the right-edge scale M5. Five scan conditions (not shown) corresponding to the scale M1 through M5 have been stored in the database 9 (refer to FIG. 1). These five scan conditions are set in such a manner that the scan time and the image quality become approximately equal to each other regardless of the width of the field of view FOV set by the slider bar 124. Accordingly, the operator 14 can perform imaging under a scan condition suitable for a body size of a subject 13 by merely selecting the field of view FOV corresponding to the body size of the subject 13 by means of the slider bar 124. Since the scan condition is automatically selected by allowing the operator 14 to move the slider bar 124a, the scan condition can simply be set.

Incidentally, although the magnetic resonance imaging apparatus has been described in the first and second embodiments, the invention can be applied even to other medical apparatuses such as a CT (Computed Tomography) apparatus.

Many widely different embodiments of the invention may be configured without departing from the spirit and the scope of the present invention. It should be understood that the present invention is not limited to the specific embodiments described in the specification, except as defined in the appended claims.

What is claimed is:

1. A scan condition setting apparatus configured to set a scan condition for use in scanning a subject, said scan condition setting apparatus comprising:
a selection device having a plurality of combinations of scan times and image quality, said selection device configured to select one of the plurality of combinations according to a manipulation of an operator, wherein the scan time and the image quality are different for each of the plurality of combinations, the scan time and the image quality based on at least a number of matrices in a frequency encode direction, a number of matrices in a phase encode direction, a repetition time, an echo train length, and an echo time associated with each of the plurality of combinations; and
a scan condition storage device configured to store a plurality of scan conditions corresponding to the plurality of combinations of scan times and image quality, wherein a scan condition corresponding to the selected combination is selected from the plurality of stored scan conditions for use when the subject is scanned, the scan condition including at least the number of matrices in the frequency encode direction, the number of matrices in the phase encode direction, the repetition time, the echo train length, and the echo time, wherein at least one of the number of matrices in the frequency encode direction and the number of matrices in the phase encode direction remains the same between at least some of the plurality of combinations as the image quality between each of the plurality of combinations increases, and wherein the repetition time and the echo time are different for at least some of the plurality of combinations.

2. The scan condition setting apparatus according to claim 1, wherein said selection device is configured to cause a display device to display a slider bar for selecting one of the plurality of combinations of scan times and image quality.

3. The scan condition setting apparatus according to claim 2, wherein the slider bar includes:
a bar for defining positions corresponding to each of the plurality of combinations of scan times and image quality; and
a slider movable between the positions defined by the bar.

4. The scan condition setting apparatus according to claim 1, wherein the echo train length is different for at least some of the plurality of combinations.

5. The scan condition setting apparatus according to claim 1, wherein the scan time and the image quality is further based on a number of addition and further wherein the number of addition remains the same between at least some of the plurality of combinations as the image quality between each of the plurality of combination increases.

6. The scan condition setting apparatus according to claim 1, wherein the scan time and the image quality is further based on an inversion time and further wherein the inversion time remains the same between at least some of the plurality of combinations as the image quality between each of the plurality of combination increases.

7. The scan condition setting apparatus according to claim 1, wherein the repetition time and the echo time are the same for at least some of the plurality of combinations.

8. The scan condition setting apparatus according to claim 1, wherein the echo train length is the same for at least some of the plurality of combinations.

9. A magnetic resonance imaging (MRI) apparatus configured to scan a subject, said MRI apparatus comprising:
a scan condition setting apparatus configured to set a scan condition for use in scanning a subject, said scan condition setting apparatus comprising:
a selection device having a plurality of combinations of scan times and image quality, said selection device configured to select one of the plurality of combinations according to a manipulation of an operator, wherein the scan time and the image quality are different for each of the plurality of combinations, the scan time and the image quality based on at least a number of matrices in a frequency encode direction, a number of matrices in a phase encode direction, a repetition time, an echo train length, and an echo time associated with each of the plurality of combinations; and
a scan condition storage device configured to store a plurality of scan conditions corresponding to the plurality of combinations of scan times and image quality, wherein a scan condition corresponding to the selected combination is selected from the plurality of stored scan conditions for use when the subject is scanned, the scan condition including at least the number of matrices in the frequency encode direction, the number of matrices in the phase encode direction, the repetition time, the echo train length, and the echo time, wherein at least one of the number of matrices in the frequency encode direction and the number of matrices in the phase encode direction remains the same between at least some of the plurality of combinations as the image quality between each of the plurality of combinations increases, and wherein the repetition time and the echo time are different for at least some of the plurality of combinations.

10. The MRI apparatus according to claim 9, wherein said selection device is configured to cause a display device to display a slider bar for selecting one of the plurality of combinations of scan times and image quality.

11. The MRI apparatus according to claim 10, wherein the slider bar includes:
a bar for defining positions corresponding to each of the plurality of combinations of scan times and image quality; and
a slider movable between the positions defined by the bar.

12. The MRI apparatus according to claim 9, wherein the echo train length is different for at least some of the plurality of combinations.

13. The medical apparatus according to claim 9, wherein the scan time and the image quality is further based on a number of addition and further wherein the number of addition increases between at least some of the plurality of combinations as the image quality between at least some of the plurality of combination increases.

14. The medical apparatus according to claim 9, wherein the scan time and the image quality is further based on an inversion time and further wherein the inversion time remains the same between at least some of the plurality of combinations as the image quality between at least some of the plurality of combination increases.

15. The medical apparatus according to claim 9, wherein the repetition time and the echo time are the same for at least some of the plurality of combinations.

16. The medical apparatus according to claim 9, wherein the echo train length is the same for at least some of the plurality of combinations.
